(19) United States
(12) Patent Application Publication
(10) Pub. No.: US 2003/0001606 A1
(43) Pub. Date: Jan. 2, 2003

(54) Probes for probe cards used for testing semiconductor devices, manufacturing method and positioning method

(75) Inventors: Gavril Bende, Bole (CH); Francisco Ramos, Neuchatel (CH)

Correspondence Address: SUGHRUE MION, PLLC, 2100 PENNSYLVANIA AVENUE, N.W., WASHINGTON, DC, 20037, US

(73) Assignee: EM MICROELECTRONIC-MARIN SA

(21) Appl. No.: 10/180,308

(22) Filed: Jun. 27, 2002

(30) Foreign Application Priority Data
Jun. 28, 2001 (EP) 01202494.9

(51) Int. Cl. G01R 31/02

(52) U.S. Cl. 324/762

(57) ABSTRACT

There is disclosed a test apparatus with probes for checking the proper working of semiconductor devices (111) immediately after their manufacture. More precisely, such systems are provided with particular probes (1), in that they include at least two tips (8, 9, 18, 29) at their end, which enters into contact with the contact bumps (2) of said semiconductor devices during the test phases. In this way, tolerances existing on the deformations undergone by said probes during tests are greater than those of probes of the prior art.

The present invention concerns a test device, more particularly a conductive test probe, capable of being arranged on a test device for testing the electric features of semiconductor devices, one end of which is provided in order to be connected to an electrically conductive path of said test device and the second end of which is capable of contacting contact bumps of said semiconductor devices during said tests.

This type of test device or probe card is commonly used by semiconductor manufacturers to test the proper working of their finished products such as wafers.

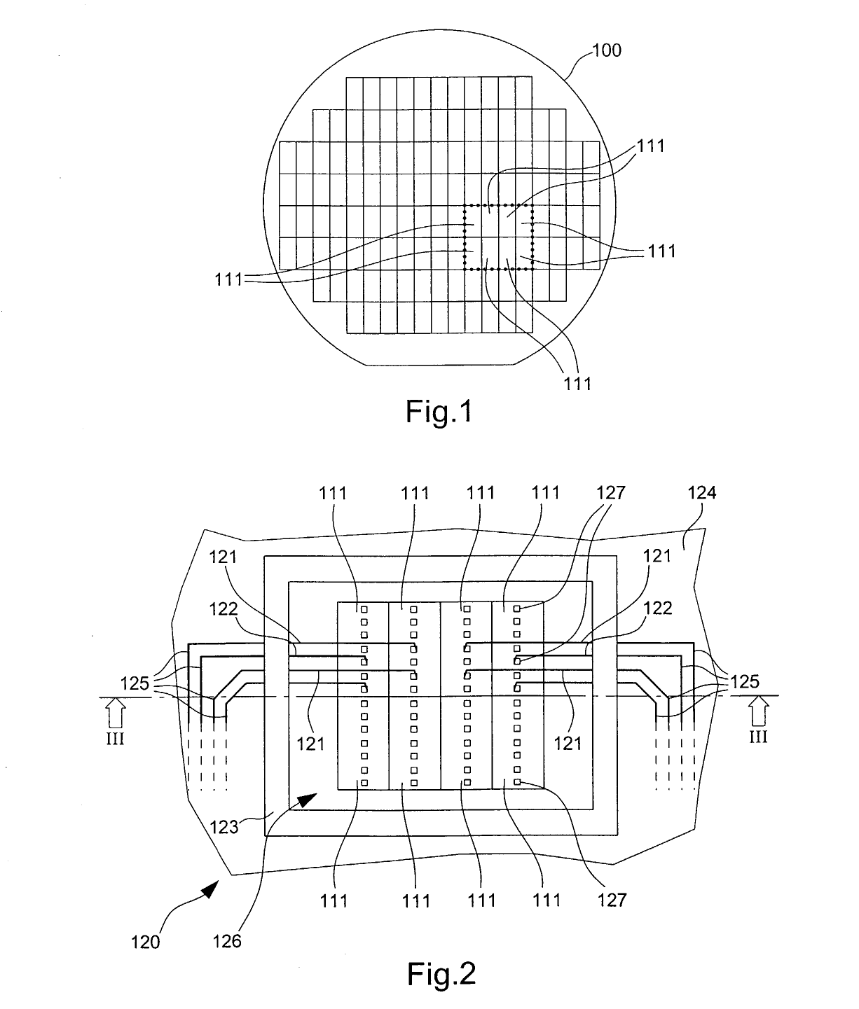

FIG. 1 shows an example of this type of semiconductor device. A wafer can be seen in this Figure, on which four columns of integrated circuits will simultaneously be tested across two rows.

In FIG. 1, the reference 100 designates a wafer of semiconductor devices including a plurality of integrated circuits 111.

FIG. 2, which is an enlarged view of the eight integrated circuits referenced in FIG. 1, shows schematically a test phase. A test device 120 can be seen, arranged above wafer 100. Said test device 120 includes test probes 121, 122 connected, via a support 123, mechanically to a substrate 124 generally made of resin, and electrically to electric conduction paths 125 carried by said substrate 124. These electric conduction paths 124 are used to establish the electrical connection between test probes 121, 122 and an electronic test circuit (not shown). Said substrate 124 further includes an aperture 126 through which said probes 121, 122 pass, so as to contact contact bumps 127, arranged on said wafer 100 in order to carry out various tests.

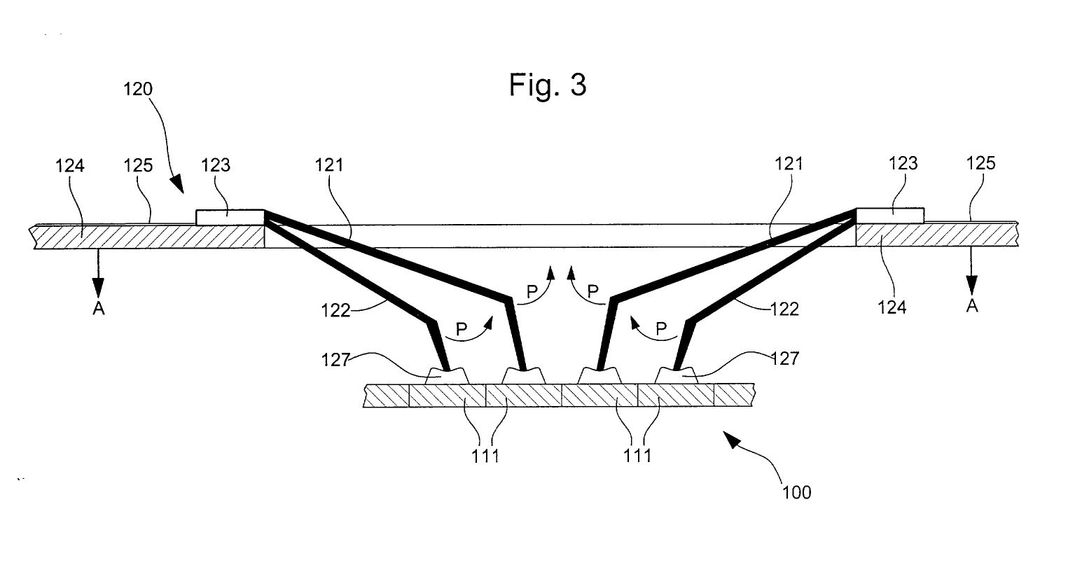

The test devices disclosed in the prior art have restrictive drawbacks. In order to carry out the test measurements, probes 121, 122 have to be fixed onto device 120 with a very high level of precision. Typically, said probes are initially positioned and fixed manually as a function of the positions of contact bumps 127, arranged on wafers 100, which constitutes laborious work. Moreover, when the tests are carried out, said probes 121, 122 are subjected to more or less significant successive deformations which may be permanent (non resilient) when the contacts are established with said bumps, as shown by the arrows marked P in FIG. 3, which is a cross-section along the line III-III of FIG. 2. These pressures lead to deformation of the probes, which may be more or less significant depending on the cross-section of said probes and the resilient properties of the material used to manufacture them. Moreover, as can be seen in FIGS. 2 and 3, when the density of contact bumps 127 on the semiconductor wafers to be tested is high, it is necessary to provide several rows of test probes on the same device 120. Consequently, since certain probes 121 are longer than others 122, they do not undergo the same mechanical stresses via the effect of the pressure exerted during the tests and thus are not deformed in the same way.

When these deformations reach a certain amplitude, there is a risk that probes 121, 122 are no longer aligned with bumps 127 which they have to contact. Moreover, a quick visual check of the alignment is not possible without an optical instrument given the small dimensions of the probes and contact bumps. Consequently, this type of test device or probe card, which is expensive to manufacture, is fragile and expensive to use.

U.S. Pat. No. 6,016,061 discloses a particular test probe structure, one end of which includes a plurality of contact zones, each having a reduced contact surface with respect to the end of conventional test probes, with a view to limiting the damage caused to the contact pads or bumps tested. This probe structure does not allow the different contact zones to move in relation to each other. Thus, during use, the different contact zones all deform in the same direction with the same amplitude and this solution does not allow the problem described hereinbefore to be resolved.

Solutions have been proposed in the prior art to overcome these difficulties. The most immediate of these solutions, which is also far from being the most interesting, consists in avoiding reducing the dimensions of the contact bumps on the semiconductor devices too much with respect to the probes. This arrangement allows the manufacturer to have more significant tolerances for the deformations which the probes may undergo during the test steps. This solution is not suited to current semiconductor industry requirements, one of the main objects of which is to optimise the space used for manufacturing its products and thus to reduce the dimensions of the contact bumps.

Another solution proposed consists in using a more or less rigid membrane which the probes pass through and which maintains the position of their second ends. U.S. Pat. No. 5,055,778 discloses such a device using a membrane made of resin or silicon. Said membrane preferably has a certain resilience for absorbing deformations due to the contact pressure of the probes on the contact bumps of semiconductor devices to be tested. This solution has, however, a drawback, in that the structure of the card assembly is particular and more complex than those of the prior art, requiring a different manufacturing process to those existing to be implemented. Moreover, said structure limits the compatibility of the components with the conventional components used on other probe cards that are already available on the market.

The main object of the present invention is thus to overcome the aforementioned drawbacks of the prior art by providing a test probe which can be adapted on existing probe cards to test semiconductor devices, able, in particular, to hold its position well over time with respect to the contact bumps of said semiconductor devices. This advantageously allows a reliable contact to be maintained with the bumps despite any deformation undergone by the probes.

The invention therefore concerns a test probe of the aforementioned type, characterised in that said probe includes, from its second end towards its first end, at least two branches joining to form a rod-like portion and capable of simultaneously contacting the same contact bump via their free ends which each ends in a pointed tip, the branches and the rod portion forming a single electric conductor.

Consequently, the probability that the probe according to the invention contacts the desired contact bump on the semiconductor device is greater than in the case of the probes of the prior art, in particular after they have been subjected to possible deformations. Indeed, as was already indicated hereinbefore, during testing of semiconductor devices, the test probes tend to become deformed because of the pressure to which they are subjected. With a probe of the type of those known in the prior art, when the deformation amplitude reaches a certain value, it may happen that the probe is no longer properly positioned with respect to the contact bump which it has to contact. With a probe according to the invention, for the same deformation amplitude, it may also happen that one of said at least two tips is no longer properly positioned. However, since the second tip is initially positioned at a different place on the bump than the place contacted by the first tip, the probability that said second tip is still properly positioned to contact said desired contact bump, is greater. It may be noted that, since said two tips are electrically connected to each other directly within the test probe, there is equivalence from the test point of view if the contact with a bump of the semiconductor device to be tested is established respectively by the first or by the second of said two tips.

Consequently, whereas a probe according to the prior art requires a maintenance operation, the probe according to the present invention still fulfills its function properly. As the period separating two successive maintenance operations is increased compared with that of the prior art, the economic advantage of the test probe according to the invention is obvious.

Moreover, as the tolerances allowed on the deformation of the probes according to the invention are greater than in the case of the probes of the prior art, the semiconductor device manufacturer can reduce the size of the contact bumps which are made on said devices.

The invention also concerns several methods for manufacturing said test probe, allowing, via different ways, a test probe to be obtained whose second end includes at least two tips.

A first method includes the steps of:

a) obtaining or manufacturing two longilineal elements made in an electrically conductive material,

b) adjusting the cross-section of said longilineal elements, by a wire drawing type operation, to obtain the desired cross-section,

c) partially connecting said longilineal elements lengthwise, by a welding, soldering or bonding operation, using an electrically conductive adhesive, from a first of their respective ends so as to define said rod, their respective free ends being kept separated so as to define said two branches.

Another method proposed in accordance with the present invention includes the steps of:

a) obtaining or manufacturing a sheet of electrically conductive material the thickness of which substantially corresponds to the desired diameter for said test probe;

b) cutting out said probe directly in said sheet by laser cutting, chemical means or photoetching, so that said rod and said branches are made in a single piece.

The invention also concerns a method for positioning test probes, in accordance with the present invention, on a probe card and relative to the positions of contact bumps arranged on a semiconductor device to be tested before commencing said tests.

The structure and methods according to the invention thus advantageously allow semiconductor devices to be tested in series, generally integrated circuits arranged on wafers, while increasing the duration between two checks and successive position adjustments of the probes compared to devices of the prior art.

The invention will be better understood with reference to the following description of an example embodiment, referring to the annexed drawings, in which:

FIG. 1, already described hereinbefore, shows schematically an elevation view of a semiconductor wafer;

FIG. 2, already described hereinbefore, shows a schematic elevation view of said wafer, above which a test device has been arranged, only a part of which is shown, including test probes according to the prior art;

FIG. 3, also already described hereinbefore, shows a schematic crosssection along the line III-III of FIG. 2, in which certain of said test probes according to the prior art are shown as they enter into contact with contact bumps of said semiconductor devices;

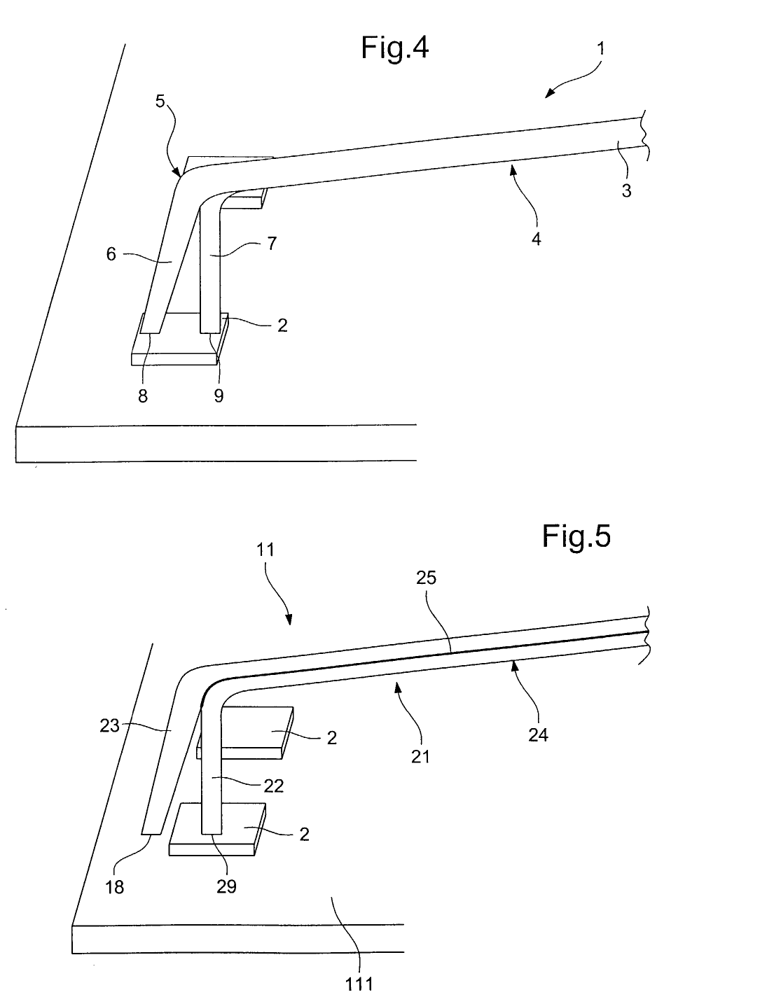

FIG. 4 is an enlarged schematic perspective view of a probe according to the present invention positioned above a contact bump of a semiconductor device;

FIG. 5 is a similar view to that of FIG. 4 in which the probe is manufactured in accordance with another embodiment of the present invention;

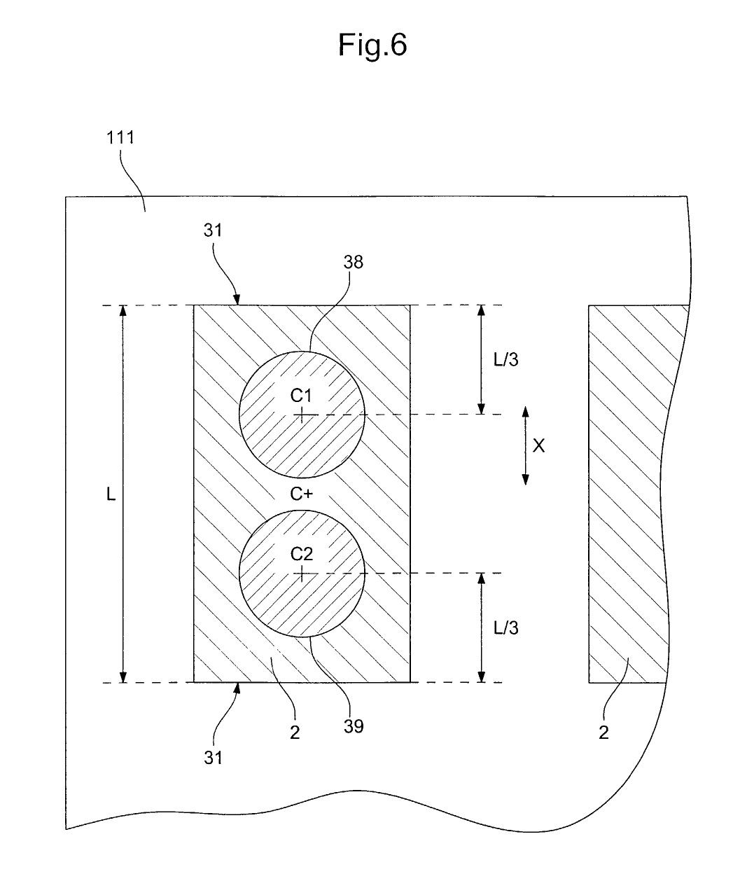

FIG. 6 is a schematic elevation view of a contact bump on which the projections of two tips of a probe according to the present invention are shown before the start of the test phases.

A probe 1 having a structure according to the invention is shown in FIG. 4, as it enters into contact with a contact bump 2 of a semiconductor device 111.

A first end 3 of said probe is typically connected to a probe card via a support-ring made of resin (not shown). This aspect will not be developed here in more detail insofar as it forms part of the general knowledge of those skilled in the art, like the detailed structure of said probe card which is of a conventional type.

Starting from said first end 3, probe 1 includes a first substantially rectilinear portion 4 ending in a bent portion 5, the whole defining a rod. Two substantially rectilinear branches 6 and 7, having different respective angles with respect to said first rectilinear portion 4, extend from said bent portion 5. Said two rectilinear branches 6 and 7 thus define two tips 8 and 9, substantially located in a same horizontal plane, and capable of contacting contact bumps 2 of semiconductor devices 111.

Typically, the test probes according to the invention are made with materials commonly used in the prior art, such as tungsten or a copper beryllium alloy (CuBe).

As regards the manufacture of said probes, several methods can be envisaged. One can first of all adapt a method usually used for making test probes of the prior art, i.e. make a metal wire of the desired cross-section by a wire drawing operation, making a cut at one of the ends of said wire lengthwise so as to obtain two branches then bending or folding said two branches with different respective angles, preferably slightly less than 90 degrees. One may of course imagine that, for example, the angle applied to one of said branches is less than 90 degrees whereas the angle applied to the second of said branches is slightly greater than 90 degrees.

One may also manufacture such test probes starting from a metal sheet of a thickness corresponding to the section desired for the probe, said sheet being cut along the profile of the test probe so as to obtain said probe directly without any additional operations. Said cutting can be achieved, for example, by laser etching, chemical means or by a photoetching method.

Two additional methods which can be envisaged to make said probes consist in using welding, soldering or bonding methods using an electrically conductive adhesive. One may, on the one hand, start with a test probe as known in the prior art onto which a second branch 7 is fixed at the bent end, thus defining a second tip 9, as shown in FIG. 4, by one of the aforementioned methods. One may, on the other hand, with reference to FIG. 5, start with two probes 11, 21 as known in the prior art and preferably with smaller sections than the usual sections, which are fixed to each other, by one of the aforementioned methods. The junction made between said two probes 11 and 21 is designated by the reference 25 in FIG. 5.

In this latter case, a first of said probes 21 is selected to be shorter than the other 11 and its branch 22, carrying tip 29 which is capable of being put into contact with contact bumps 2 during tests, is bent or folded at a greater angle, with respect to first rectilinear portion 24, than the corresponding branch 23, carrying tip 18, of the second of said probes 11. In this way, said respective branches 22, 23 of said probes 11, 21 are separated and the assembly obtained thus defines a single probe including two tips 18, 29.

Furthermore and in accordance with the invention, the distance between said two branches 22, 23 is determined from the dimensions of contact bumps 2 to be tested, so that said two tips 18, 29 can initially simultaneously contact the same contact bump 2 of the semiconductor device.

As was indicated previously, during the tests of the semiconductor devices, the test probes undergo more or less significant pressure which causes their deformation. The probes are positioned on a probe card via a support so that their tips, which are capable of contacting the contact bumps, are substantially situated in a same horizontal plane. The card is then generally brought closer to the semiconductor devices to be tested from the top downwards (shown by arrows A in FIG. 3) until the probes enter into contact with said bumps. However, the contact bumps on the semiconductor devices are of variable height, which is why the probe card is lowered more than is actually necessary, to ensure that all the probes actually establish contact with the corresponding contact bump on the semiconductor device to be tested. Consequently, the test probes undergo more or less significant pressure depending on the real height of the corresponding contact bump. Said probes consequently tend to become deformed and transmit said pressure to the probe card, which is thus also capable of deforming to finally have a surface evenness defect. The fact that the probe card is lowered closer to the semiconductor device than actually necessary is also intended to compensate for the gradual deformation of the probes and the probe card.

When one examines more precisely the deformation which the test probes undergo, it can be seen that they can result in the establishment of a poor contact with the corresponding bump, or no contact at all.

This is why, as is apparent in FIG. 5, when the test probe according to the invention is deformed until one of the two tips 18 can no longer contact the corresponding bump 2, the second tip 29 still guarantees contact. One may in fact consider that, as a first approximation, according to the structure of the probe in accordance with the invention, said first tip 18 corresponds to the single tip of a probe of the prior art. Thus, when a probe of the prior art is deformed to the point of requiring an awkward maintenance operation, the probe according to the present invention can still operate properly owing to the presence of said second tip 29.

It may also be noted that, because of the distance separating the junction of the branches of their respective tips, the branches are capable of being deformed differently to each other, i.e. in different directions and with different respective deformation amplitudes. Thus, when one of tips 18 or 29 undergoes a significant deformation, for example to the point of no longer being aligned with the contact bump which it has to test, it is possible for the other tip not to be deformed, or only very slightly and to be aligned still with said contact bump. This particular feature is advantageous from the point of view of utilisation costs, since it statistically allows the period separating two successive maintenance operations of the test probes according to the present invention to be extended compared to the probes of the prior art.

Starting from this principle, one can deduce therefrom a method for optimising the initial position of probe 1 according to the invention, i.e. before the start of tests and thus of deformations, on the probe card (FIG. 4). In order to do this, account must be taken of the dimensions and the position of the corresponding contact bump 2 on the semiconductor device to be tested. As has already been mentioned, the distance between the two branches 6, 7 of probe 1 according to the invention also depends on the dimensions of the bumps to be tested.

FIG. 6 shows a top view of a contact bump 2 on which are schematised the orthogonal projections 38, 39 of said tips 8, 9 of probe 1 according to the invention. It can be said, in a certain way, that tips 8, 9 must preferably be centred on contact bump 2, insofar as the direction of the deformations is random, both for the probe and for each of its branches. Indeed, the only tendency which can be deduced from practice indicates that the most significant deformations occur in the direction shown by the double arrow referenced X in FIG. 6.

Thus, in the case of a contact bump 2 of substantially rectangular shape and of length referenced L in FIG. 6, chosen here by way of non limiting example, the test probe will preferably be positioned so that the centre Cl of said projection 38 of a first of tips 8 is located substantially at a distance L/3 from the small side 31 of bump 2 which is the closest to said tip 8. Consequently, the distance arranged between said two tips 8, 9 of probe 1 will preferably be chosen such that the centre C2 of said projection 39 of the second of said tips 9 is also located at a distance L/3 from the other small side 31 of said contact bump 2. In other words, the centre of the segment defined by C1 and C2 preferably coincides with the geometric centre C of the contact bump. Since this configuration has the best guarantee of contact between the probe and the corresponding successive bumps over time, it constitutes a preferred embodiment for the method for positioning the probe on a probe card according to the invention.

It should be noted that, owing to the present invention, a manufacturer of semiconductor devices can advantageously reduce the dimensions of the contact bumps arranged on said devices and thus reduce the global size of said devices. This reduction allows said manufacturer to use less raw material for manufacturing said devices, which constitutes a main advantage of the present invention.

The preceding description corresponds to preferred embodiments of the invention and should in no way be considered as limitative, as regards more particularly, the shape, inclination and materials described for the test probe, the manufacturing methods and the described shape of the contact bumps.

What is claimed is

1. A test apparatus, for testing the electric features of semiconductor devices, including an insulating substrate carrying electric conduction paths connected, on the one hand, to an electronic test circuit and, on the other hand, to electrical terminals located on said substrate, a support provided to be arranged on said substrate and to which a plurality of test probes are mechanically and electrically connected via a first of their respective ends, said support including electrical connectors provided to connect said first ends of the probes to said electrical terminals of said substrate, the second respective ends of said probes being provided to contact contact bumps arranged on said semiconductor devices, wherein each of said probes includes, from its second end towards its first end, at least two branches joining to form a rod-like portion and capable of simultaneously contacting the same contact bump via their free ends which each ends in a pointed tip, the branches and the rod portion forming a single electrical conductor.

2. A conductive test probe capable of being arranged on a test apparatus, in particular according to claim 1, for testing the electric features of semiconductor devices, provided to be mechanically and electrically connected to a support of said test apparatus via a first end, the second end being provided to contact contact bumps arranged on said semiconductor devices, wherein each of said probes includes, from its second end towards its first end, at least two branches joining to form a rod-like portion and capable of simultaneously contacting the same contact bump via their free ends which each ends in a pointed tip, the branches and the rod portion forming a single electrical conductor.

3. The test probe according to claim 2, wherein said rod portion includes at least one substantially rectilinear portion.

4. The test probe according to claim 2, wherein said rod portion includes, from said first end, a first substantially rectilinear portion followed by a bent portion followed by said two substantially rectilinear branches that are shorter than said rod portion (4, 5, 24), having different respective angles with respect to said rod portion so as to define two distinct tips (8, 9, 18, 29) at their respective free ends.

5. The test probe according to claim 2, wherein starting from said first end of the probe, said rod portion includes two longilineal elements of respective small sections, partially welded, soldered or bonded using an electrically conductive adhesive lengthwise, their respective free ends being separated so as to define said two branches.

6. The test probe according to claim 4, wherein starting from said first end of the probe, said rod portion includes two longilineal elements of respective small sections, partially welded, soldered or bonded using an electrically conductive adhesive lengthwise, their respective free ends being separated so as to define said two branches.

7. The test probe according to claim 2, wherein during use, said branches are capable of undergoing different respective deformations.

8. The test probe according to claim 4, wherein during use, said branches are capable of undergoing different respective deformations.

9. The test probe according to claim 6, wherein during use, said branches are capable of undergoing different respective deformations.

10. A method for manufacturing a test probe capable of being arranged on a test apparatus, in particular according to claim 1, for testing the electric features of semiconductor devices, provided to be mechanically and electrically connected to a support of said test apparatus via a first end, the second end being provided to contact contact bumps arranged on said semiconductor devices, wherein each of said probes includes, from its second end towards its first end, at least two branches joining to form a rod-like portion and capable of simultaneously contacting the same contact bump via their free ends which each ends in a pointed tip, the branches and the rod portion forming a single electrical conductor, including the steps of:
a) providing a wire made of electrically conductive material having a determined section,
b) cutting said wire, from one of its ends, over a part of its length so as to obtain said two branches of substantially identical sections, whereas the uncut part of said wire forms said rod portion;
c) bending said two branches with different respective angles with respect to said rod portion.

11. A method for manufacturing a test probe capable of being arranged on a test apparatus, in particular according to claim 1, for testing the electric features of semiconductor devices, provided to be mechanically and electrically connected to a support of said test apparatus via a first end, the second end being provided to contact contact bumps arranged on said semiconductor devices, wherein each of said probes includes, from its second end towards its first end, at least two branches joining to form a rod-like portion and capable of simultaneously contacting the same contact bump via their free ends which each ends in a pointed tip, the branches and the rod portion forming a single electrical conductor, including the steps of:
a) providing two longilineal elements made of electrically conductive material having a determined section,
b) partially connecting said longilineal elements lengthwise, from a first of their respective ends so as to define said rod portions and to form an electric contact between them, their respective free ends being kept separated so as to define said two branches.

12. The method for manufacturing a test probe according to claim 11, wherein in step b), the connection of said longilineal elements is achieved by a welding, soldering or bonding operation using an electrically conductive adhesive.

13. A method for manufacturing a test probe capable of being arranged on a test apparatus, in particular according to claim 1, for testing the electric features of semiconductor devices, provided to be mechanically and electrically connected to a support of said test apparatus via a first end, the second end being provided to contact contact bumps arranged on said semiconductor devices, wherein each of said probes includes, from its second end towards its first end, at least two branches joining to form a rod-like portion and capable of simultaneously contacting the same contact bump via their free ends which each ends in a pointed tip, the branches and the rod portion forming a single electrical conductor, including the steps of:
a) providing a sheet of electrically conductive material the thickness of which substantially corresponds to the desired diameter of said test probe,
b) cutting said probe directly out of said sheet such that said rod portion and said branches are made in a single piece.

14. The method for manufacturing a test probe according to claim 13, wherein said cutting step b) is achieved by laser cutting, chemical means or photoetching.

15. A method for positioning, on a test apparatus, test probes according to claim 2, said apparatus further including a support provided to be arranged on said substrate and to which a plurality of said test probes are mechanically and electrically connected via a first of their respective ends, said support including electrical connectors provided to connect said first ends of said probes to said electrical terminals of said substrate, the second respective ends of said probes each including at least two branches whose pointed tips are provided to contact contact bumps arranged on said semiconductor devices, wherein said at least two branches of each of said probes are positioned, prior to the start of the tests, so that said branches simultaneously contact the same contact bump via their tips.

16. The positioning method according to claim 15, wherein said at least two branches of each of the test probes are positioned such that the geometric centre of the projections of said at least two tips on said contact bump tested coincide with the geometric centre of said contact bump tested.
